(19) United States
(12) Patent Application Publication
(10) Pub. No.: US 2026/0276746 A1
(43) Pub. Date: Sep. 17, 2026

(54) ASSEMBLY FOR COMPENSATING FOR THE TEMPERATURE OF A FIRST COMPONENT OF A FIRST PART

(71) Applicant: Endress+Hauser SE+Co. KG, Maulburg (DE)

(72) Inventors: Dietmar Frühauf, Lörrach (DE); Raphael Kuhnen, Schliengen (DE); Rebecca Petrich, Ilmenau (DE)

(21) Appl. No.: 19/168,136

(22) PCT Filed: Feb. 19, 2024
(86) PCT No.: PCT/EP2024/054136

§ 371 Date: Sep. 23, 2025

(30) Foreign Application Priority Data
Mar. 28, 2023 (DE) 10 2023 107 891.7

(51) Int. Cl. G01R 33/00; G01R 33/028

(52) U.S. Cl. CPC G01R 33/0082; G01R 33/0286

(57) ABSTRACT

An arrangement for temperature compensation of a first component of a first part comprises the first part with the first component which is embodied mechanically oscillatably and magnetoelectrically, an electronics which is embodied to excite the first component by means of a first excitation signal such that mechanical oscillations are executed, and to receive the mechanical oscillations of the first component and convert them into a first received signal, and a compensation means which is adapted to compensate an influence of temperature on the first received signal.

The invention relates to an arrangement for temperature compensation of a first component of a first part.

Field devices for monitoring and/or determining at least one, for example chemical or physical, process variable of a fill substance are known in a wide variety of embodiments in the state of the art. In the context of the invention, in principle, referred to as field devices are all measuring devices, or sensor arrangements, which are applied near to a process and which deliver, or process, process relevant information. Thus included are also remote I/Os, radio adapters, and, generally, electronic components, which are arranged at the field level. A large number of such field devices are manufactured and sold by the Endress +Hauser group of companies.

Many different field devices rest on the measuring of magnetic fields and determining and/or ascertaining the desired process variable and/or characteristic variable based on a variable related with the magnetic field. For detecting the magnetic field, in such case, as a rule, various types of magnetic field sensors are used. The accuracy of such types of field devices depends in large measure on the accuracy of measurement of the magnetic field sensors. Moreover, field devices can also comprise actuators, which exert forces under the influence of magnetic fields.

Magnetoelectrical sensors serve for the detection of magnetic fields and can operate based on the mechanical force coupling of magnetostrictive and piezoelectric materials. There are also magnetoelectric sensors based on multiferroic materials. Magnetoelectrical actuators, in contrast, serve for exerting a force under the influence of a magnetic field.

Magnetostrictive materials are characterized by deformation of the material as a result of an applied magnetic field. In this connection, one distinguishes between Joule magnetostriction, in the case of which a length change occurs as a result of a change of the magnetization, the Villary effect, the inverse magnetostrictive effect, in the case of which a change of the magnetic properties occurs as a result of a mechanical stress, and the Delta-E effect, which describes a change of the modulus of elasticity as a result of a change of the magnetization. Magnetostrictive materials are, for example, ferromagnetic transition metals, such as iron, nickel or cobalt or their alloys, e.g. alloys of cobalt and iron, gallium and iron, thus galfenol, or terbium, dysprosium and iron, e.g. terfenol, as well as various additional combinations of the transition metals with rare earths or various ferromagnetic glasses. Piezoelectric materials are characterized by the change of electrical polarization and, thus, the occurrence an electrical voltage as a result of an elastic deformation. Piezoelectrical materials are, for example, lead zirconate titanate, polyvinylidene fluoride or aluminum nitride.

In the case of a magnetoelectric sensor, a magnetostrictive material is fixedly coupled to a piezoelectric material. As a result of an applied magnetic field, the magnetostrictive material experiences a length change in the direction of the acting magnetic field and/or a change of the modulus of elasticity. The longitudinal expansion exerts a force on the piezoelectric material, which leads to a change of the polarization and, as a result, to the occurrence of a voltage, which is electrically detectable. A change of the modulus of elasticity, in turn, leads to a changed transfer behavior, which is likewise detectable. For example, it is known, in this connection, to excite mechanical oscillations in the magnetoelectric sensor by means of the piezoelectric material. A change of the modulus of elasticity as a result of an applied magnetic field leads, in such case, to a changed oscillatory behavior, which, for example, is evaluatable based on a frequency and/or an amplitude of the mechanical oscillations.

Numerous different embodiments are known for building a magnetoelectric sensor. In many cases, a multi-ply, layer structure is used, which comprises at least one layer of the magnetostrictive material, a layer of the piezoelectric material and, in given cases, an electrode for sensing the voltage. Often the layer structure has the form of a strip, which is secured on one end. Application of a magnetic field leads then to a bending of the strip and to the occurrence of an electrical voltage signal as received signal.

Under the influence of a periodic, time variable, magnetic field with a predeterminable frequency, or other suitable excitation signal, magnetoelectric sensors execute forced oscillations. In such case, resonant oscillations are especially advantageous, since, in such case, comparatively small magnetic field changes bring about comparatively large changes of the sensor behavior Such a magnetoelectric sensor is described, for example, in DE 10 2021 109 408 A1 .

Besides magnetic field changes, also temperature exercises an influence on the electrical voltage signal, since the physical properties of the magnetoelectric sensor are, as a general rule, temperature dependent. The effect of temperature on the electrical voltage signal is, however, frequently undesirable, especially when the magnetoelectric sensor is applied in process installations with, at times, greatly varying temperatures. With just the electrical voltage signal, it is, however, not possible to separate the influence of temperature from the influence of magnetic field changes.

Based on the above, an object of the invention is to provide an arrangement, which enables, in simple manner, a compensating of the temperature effect.

According to the invention, the object is achieved by an arrangement for temperature compensation of a first component of a first part, comprising
the first part with the first component, which is embodied mechanically oscillatably and magnetoelectrically,
an electronics, which is embodied to excite the first component by means of a first excitation signal, such that mechanical oscillations are executed, and to receive the mechanical oscillations of the first component and to convert such into a first received signal,
a compensation means, which is adapted to compensate an influence of temperature on the first received signal.

The first component is embodied, with excitation by means of the first excitation signal, to execute mechanical oscillations and has magnetoelectric properties. Especially, the first component can be embodied in part as a rod or strip secured on one end, or as a bridge secured on both ends.

The first excitation signal is preferably produced based on the first received signal, especially a frequency of the first received signal. In such case the first excitation signal can be produced in such a manner that the mode of the mechanical oscillations corresponds to a resonant frequency of the first component.

According to the invention, the arrangement includes a compensation means, which enables compensation of an influence of temperature on the first received signal. Especially, the compensation means is embodied using a difference principle to compensate an influence of temperature on the first received signal.

In an embodiment, the first component includes a first layer of a piezoelectric material and a second layer of a magnetostrictive material or a multiferroic material. The first component can be made, for example, by means of coating technologies known per se with or without predetermined substrate, for example, processes of silicon technology can be applied. In an embodiment, involved in the case of the first component is a MEMS element, thus, a micro-electro-mechanical system (MEMS). Especially, the first layer can be embodied sectionally in the form of a strip secured on one end or two ends.

Preferably, the arrangement includes a magnetic field unit, which is embodied to produce a first magnetic field at least in the region of the first component. The first magnetic field can serve as an offset magnetic field, in order to determine changes of the first magnetic field by means of the first part.

In an additional embodiment, the electronics unit is embodied to determine, based on the first received signal, a change of the first magnetic field brought about by an environment of the first part. The first magnetic field, and the change of the first magnetic field, are evaluated based on the first received signal, which is an electrical voltage signal. For example, the first part can be applied as magnetic field sensor for determining and/or monitoring a process variable of a fill substance.

In a first form of embodiment, the compensation means is adapted to influence the first component in such a manner that, within a defined period of time, a change of the first magnetic field effects no change of the first received signal. In the first form of embodiment, the first component is influenced in such a manner that for a defined time period the first component acts as a duplicate of itself. During the defined period of time, the first component is still excited with the first excitation signal, such that mechanical oscillations are executed and a first received signal received. Since, within the defined period of time, the first component is not influenced by a change of the first magnetic field, an influence of temperature on the first received signal can be determined without contribution of the change of the first magnetic field. The contribution of the first magnetic field to the first received signal is, thus, constant. In given cases, the contribution of the first magnetic field to the first received signal is known. Thus, an influence of temperature on the first received signal can be compensated. Preferably, the compensation means is adapted to influence the first component repeatedly in such a manner that, within a defined period of time, a change of the first magnetic field effects no change of the first received signal.

In a further development of the first form of embodiment, the compensation means is adapted within a defined period of time to saturate the first component magnetically by means of the first magnetic field unit or a second magnetic field unit. Due to the (temporary) magnetic saturation of the first component, a change of the first magnetic field effects no change of the first received signal in the defined time period, such that an influence of temperature on the first received signal can be determined without influence of a change of the first magnetic field.

In an alternative further development of the first form of embodiment, the compensation means is adapted by means of a second magnetic field unit to produce a second magnetic field, which compensates the first magnetic field within a defined period of time. Since the first magnetic field is compensated within a defined period of time, the first received signal can be determined without influence of the first magnetic field.

In a second form of embodiment, the arrangement includes a second component, which is embodied as an equally constructed duplicate of the first component, wherein the electronics is further embodied to excite the second component by means of a second excitation signal, such that mechanical oscillations are executed, and to receive the mechanical oscillations of the second component and to convert them into a second received signal, wherein the second component is arranged in such a manner that a change of the first magnetic field effects no change of the second received signal, and wherein the compensation means is adapted to compensate an influence of temperature on the first received signal by means of the first component and the second component.

The second component is embodied as an equally constructed duplicate of the first component. It has, thus, the same mechanically oscillatable construction and the same magnetostrictive properties as the first component. However, the second component is so arranged that a change of the first magnetic field effects no change of the second received signal of the second component. The influence of a change of the first magnetic field on the first received signal is constant, while an influence of temperature on the first received signal varies depending on temperature. In this way, an influence of temperature on the first received signal can be compensated by means of the first component and the second component.

In a further development of the second form of embodiment, the second component is arranged at such an angle to the first magnetic field that the second received signal is essentially independent of the first magnetic field. Typically, the second received signal of the second component depends on the angle between the second component and the first magnetic field. Preferably, such an angle between the second component and the first magnetic field is selected that the contribution of the first magnetic field to the second received signal is negligible or zero.

In an alternative further development of the second form of embodiment, the second component is arranged adjoining a magnetic shielding, which is embodied and/or arranged in such a manner that the second component is completely shielded from the first magnetic field. By means of the magnetic shielding, it results that the second received signal has no or negligible contribution of the first magnetic field.

In another alternative further development of the second form of embodiment, the second component is arranged in such a manner relative to the first magnetic field that the second component is permanent magnetically saturated. Since the second component is permanent magnetically saturated, the second received signal has no or a constant contribution of the first magnetic field. The second received signal changes, thus, only because of temperature.

In a third form of embodiment, the arrangement includes a third non-magnetic component, which has essentially the same thermomechanical properties as the first component, wherein the electronics is further embodied to excite the third component by means of a third excitation signal, such that mechanical oscillations are executed, and to receive the mechanical oscillations of the third component and convert them into a third received signal, wherein the compensation means is adapted to compensate an influence of temperature on the first received signal by means of the first component and the third component.

The third component is embodied non-magnetically and has essentially the same thermomechanical properties as the first component. The concept “essentially the same thermomechanical properties” means in the context of this application that the differences in the thermomechanical properties of the first component and the third component are for the compensation of an influence of temperature on the first received signal negligible or small, however, known. Since the third component is embodied non-magnetically, the third received signal has no contribution of the first magnetic field. Since the third component has essentially the same thermomechanical properties as the first component, the third received signal can be utilized for compensating an influence of temperature on the first received signal.

The invention will now be explained in greater detail based on the appended drawing, the figures of which show as follows:

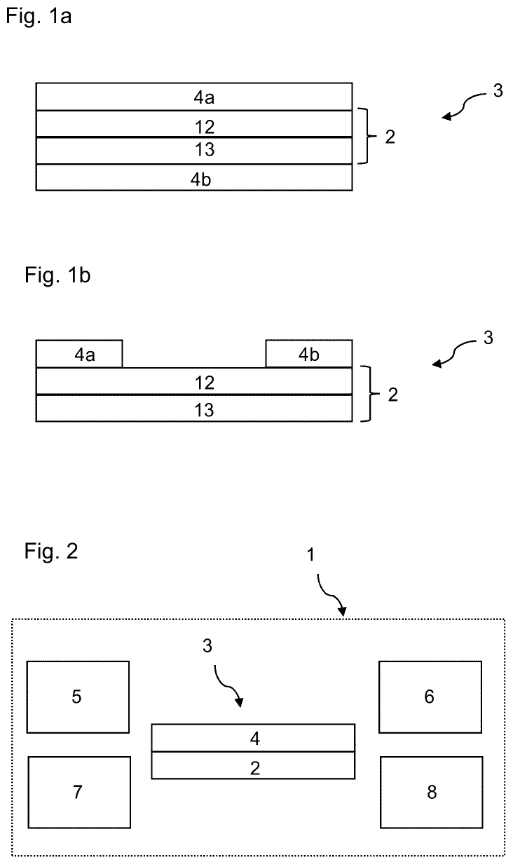

FIG. 1a,b two embodiments of the first part.

FIG. 2 a first embodiment of the arrangement of the invention.

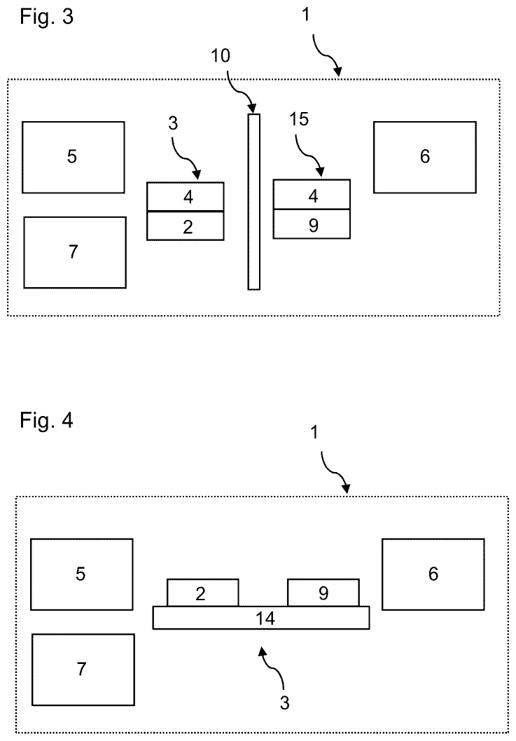

FIG. 3 a second embodiment of the arrangement of the invention.

FIG. 4 a third embodiment of the arrangement of the invention.

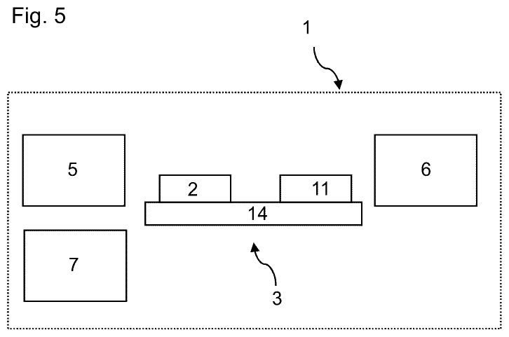

FIG. 5 a fifth embodiment of the arrangement of the invention.

Shown in FIG. 1a,b are two preferred embodiments for the first part 3. The first part 3 of FIG. 1a has a first layer 12 of a piezoelectric material and a second layer 13 of a magnetostrictive material, which are arranged on top of one another and mechanically coupled with one another. The first part 3 is constructed in the form of a layer structure, for example, in the form of a MEMS component. In other embodiments, other layers or, additionally, a substrate can be present. The first layer 12 of piezoelectric material can be embodied sectionally as a strip. Instead of the first layer 12 and the second layer 13, the first component 2 can also comprise a multiferroic material having magnetoelectric properties.

Preferably, the first part 3 includes at least one electrode 4. On the first layer 12 of the piezoelectric material, at least one electrode 4 of an electrically conductive material can be applied as a first electrode 4a, which serves for registering a received signal from the first component 2 in the form of an electrical voltage. Preferably, the at least one electrode 4 extends over a large part of, or essentially completely along, a surface of the first component 2, here a piezoelectric layer 12 of the component 2. The first part 3 can be so embodied that it has a plurality of electrodes. A second electrode can be the second layer 13 of magnetostrictive material, since magnetostrictive materials are typically electrically conductive. Then the electrical voltage can be tapped between the first electrode 4a and the second layer 13. It is, however, likewise an option to provide a separate second electrode 4b, such as shown in FIG. 1a, and to sense the electrical voltage between the two electrodes 4a and 4b.

In the embodiment shown in FIG. 1a, the second electrode is embodied as a rear electrode, which is arranged in an end region of the first part 3 opposite the first electrode 4a. Alternatively, the two electrodes 4a and 4b can be applied in different regions of the surface of the first layer 12 of piezoelectric material, such as shown in FIG. 1b. In such case, the first electrode 4a is an exciter electrode and the second electrode 4b a receiving electrode. The two electrodes 4a and 4b are electrically separated from one another.

FIG. 2 shows a first embodiment of the arrangement 1 of the invention, which has, besides the first part 3, an electronics 5 and a compensation means 6. Electronics 5 is embodied to excite the first component 2 by means of a first excitation signal, such that mechanical oscillations are executed, and to receive the mechanical oscillations of the first component 2 and convert them into a first received signal. Especially, electronics 5 is electrically connected with the at least one electrode 4. The first received signal depends, in such case, on a magnetic field lying on the component 2 and a temperature. For temperature compensation, the compensation means 6 is provided and adapted to compensate an influence of temperature on the first received signal.

Optionally, the arrangement 1 can have a first magnetic field unit 7, which produces a first magnetic field B1 at least in the region of the first component 2. The magnetic field B1 can serve as an offset magnetic field, whose changes are detectable by means of the first received signal. A change of the first magnetic field B1 can be brought about by an environment of the first part 3. For example, the first part 3 can be secured on a containment, in which a fill substance is located. Based on the first received signal, a process variable, especially a fill level or limit level, of the fill substance can be determined and/or monitored.

In order to compensate an influence of temperature on the first received signal, three alternative forms of embodiment are provided.

Thus, the compensation means 6 in the first form of embodiment can be embodied to influence the first component 2 in such a manner that, within a defined period of time, a change of the first magnetic field B1 effects no change of the first received signal, such as shown in FIG. 2. For example, the compensation means 6 can be adapted to saturate the first component 2 within a defined period of time magnetically by means of the first magnetic field unit 7 or a second magnetic field unit 8. Alternatively, the compensation means 6 can be adapted to produce by means of the second magnetic field system 8 a second magnetic field B2, which compensates the first magnetic field B1 within a defined period of time.

During the defined period of time, in which the first component 2 is magnetically saturated or the first magnetic field B1 is compensated, the first component 2 is excited by means of the electronics and the first excitation signal, such that mechanical oscillations are executed. The electronics can be embodied to receive the mechanical oscillations of the first component 2 and to convert them into a fourth or fifth received signal. The compensation means 6 can be adapted, based on the first received signal and the fourth or fifth received signal, to compensate an influence of temperature on the first received signal.

In the second form of embodiment, the arrangement 1 includes a second component 9, which is embodied as an equally constructed duplicate of the first component 2. Especially, the second component 9 is embodied identically to the first component 2. The electronics is embodied to excite the second component 9 by means of a second excitation signal, such that mechanical oscillations are executed, and to receive the mechanical oscillations of the second component 9 and to convert them into a second received signal. Based on the first component 2 and the second component 9, especially based on the first received signal and the second received signal, the compensation means 6 compensates an influence of temperature on the first received signal. In such case, the second component 9 is arranged in such a manner that a change of the first magnetic field B1 effects no change of the second received signal.

An option for arrangement of the second component 9 is shown in FIG. 3. The second component 9 is arranged adjoining a magnetic shielding 10, which is embodied to shield the second component 9 from the first magnetic field B1. Other options for the arrangement are shown in FIG. 4. Thus, the second component 9 can be arranged at such an angle to the first magnetic field B1 that the second received signal is essentially independent of the first magnetic field B1 or the second component 9 is arranged relative to the first magnetic field B1 in such a manner that the second component 9 is permanent magnetically saturated. The second component 9 can be arranged separately from the first part 3, such as shown, by way of example, in FIG. 3, or it can be arranged together with the first component 2 on a shared substrate 14 of the part 3, such as shown in FIG. 4.

A third form of embodiment is shown in FIG. 5. In such case, the arrangement 1 includes a third component 11. The third component 11 is non magnetic, i.e. it is not influenced in its properties by the first magnetic field. Moreover, the third component 11 has essentially the same thermomechanical properties as the first component 2. The third component 11 can together with the first component 2 be incorporated by the first part 3, or be arranged separately from the first part 3. The third component 11 is excited by means of a third excitation signal, such that mechanical oscillations are executed, wherein a third received signal is produced. The compensation means 6 is adapted to compensate an influence of temperature on the first received signal by means of the first component 2 and the third component 11, especially based on the first received signal and the third received signal.

### LIST OF REFERENCE CHARACTERS

1 arrangement
2 first component
3 first part
4 electrode
4a first electrode
4b second electrode
5 electronics
6 compensation means
7 first magnetic field unit
8 second magnetic field unit
9 second component
10 magnetic shielding
11 third component
12 first layer
13 second layer
14 substrate
15 second part
B1 first magnetic field
B2 second magnetic field

1-12. (canceled)

13. An arrangement for temperature compensation of a first component of a first part, comprising:
the first part with the first component which is embodied mechanically oscillatably and magnetoelectrically;
an electronics, which is embodied to excite the first component by means of a first excitation signal such that mechanical oscillations are executed, and to receive the mechanical oscillations of the first component and to convert the received mechanical oscillations into a first received signal; and
a compensation means which is adapted to compensate an influence of temperature on the first received signal.

14. The arrangement as claimed in claim 13,
wherein the first component includes a first layer of a piezoelectric material and a second layer of a magnetostrictive material or a multiferroic material.

15. The arrangement as claimed in claim 14, further comprising:
a first magnetic field unit which is embodied to produce a first magnetic field at least in a region of the first component.

16. The arrangement as claimed in claim 13,
wherein the electronics is embodied to determine, based on the first received signal, a change of the first magnetic field brought about by an environment of the first part.

17. The arrangement as claimed in claim 16,
wherein the compensation means is adapted to influence the first component in such a manner that, within a defined period of time, a change of the first magnetic field effects no change of the first received signal.

18. The arrangement as claimed in claim 17,
wherein the compensation means is adapted within a defined period of time to saturate the first component magnetically by means of the first magnetic field unit or a second magnetic field unit.

19. The arrangement as claimed in claim 17,
wherein the compensation means (6) is adapted by means of a second magnetic field unit (8) to produce a second magnetic field (B2), which compensates the first magnetic field (B1) within a defined period of time.

20. The arrangement as claimed in claim 13, further comprising:
a second component which is embodied as an equally constructed duplicate of the first component,
wherein the electronics is further embodied to excite the second component by means of a second excitation signal such that mechanical oscillations are executed, and to receive the mechanical oscillations of the second component and to convert the received mechanical oscillations into a second received signal,
wherein the second component is arranged in such a manner that a change of the first magnetic field effects no change of the second received signal,
wherein the compensation means is adapted to compensate an influence of temperature on the first received signal by means of the first component and the second component.

21. The arrangement as claimed in claim 20,
wherein the second component is arranged at such an angle to the first magnetic field that the second received signal is independent of the first magnetic field.

22. The arrangement as claimed in claim 20,
wherein the second component is arranged adjoining a magnetic shielding which is embodied and/or arranged in such a manner that the second component is completely shielded from the first magnetic field.

23. The arrangement as claimed in claim 20,
wherein the second component is arranged in such a manner relative to the first magnetic field that the second component is permanently magnetically saturated.

24. The arrangement as claimed in claim 13, further comprising:
a third non-magnetic component which has the same thermomechanical properties as the first component,
wherein the electronics is further embodied to excite the third component by means of a third excitation signal such that mechanical oscillations are executed, and to receive the mechanical oscillations of the third component and convert the received mechanical oscillations into a third received signal,
wherein the compensation means is adapted to compensate an influence of temperature on the first received signal by means of the first component and the third component.
